(19) United States
(12) Patent Application Publication
(10) Pub. No.: US 2005/0232146 A1
(43) Pub. Date: Oct. 20, 2005

(54) System and method for recovering a damaged routing path in a mobile network

(75) Inventors: Sung-Jin Lee, Suwon-si (KR); Hyun-Jeong Kang, Seoul (KR); Jong-Keun Na, Seongnam-si (KR); Seong-Ho Cho, Seoul (KR)

Correspondence Address: DILWORTH & BARRESE, LLP, 333 EARLE OVINGTON BLVD., UNIONDALE, NY, 11553, US

(73) Assignee: SAMSUNG ELECTRONICS CO., LTD., Suwon-si (KR)

(21) Appl. No.: 11/109,205

(22) Filed: Apr. 19, 2005

(30) Foreign Application Priority Data
Apr. 19, 2004 (KR) 2004-26779

(51) Int. Cl. G01R 31/08

(52) U.S. Cl. 370/225

(57) ABSTRACT

A system and method in a mobile network in which a first router manages a first subnet including at least one second router and the at least one second router manages a second subnet including at least one mobile node. In a method for recovering a routing path between the first router and the at least one mobile node, the first router receives, from the at least one second router, information of neighboring routers included in the first subnet, and stores the received neighboring router information. An occurrence of routing path failure is recognized when a periodic report message is not received from the at least one second router within a preset time. An alternative router is selected from among the neighboring routers when the failure occurrence is recognized, and a routing path recovery request is sent to the alternative router. Data is routed to the at least one mobile node through the alternative router when the alternative router positively responds to the routing path recovery request.

### PRIORITY

This application claims priority to an application entitled “SYSTEM AND METHOD FOR RECOVERING A DAMAGED ROUTING PATH IN A MOBILE NETWORK”, filed in the Korean Intellectual Property Office on Apr. 19, 2004 and assigned Serial No. 2004-26779, the contents of which are incorporated herein by reference.

### BACKGROUND OF THE INVENTION

1. Field of the Invention

The present invention relates generally to a mobile network, and more particularly to a system and method for recovering a routing path in Mobile Internet Protocol version 6 (MIPv6).

2. Description of the Related Art

An Internet Protocol (IP) network, i.e., an Internet network, is being extended, and simultaneously a wired section within a cellular network is developing into an IP-based Internet network. Devices that were developed for operation only within a wired environment must provide service, while now maintaining seamless continuity in a high-speed wireless environment.

More specifically, the previous Internet environment took into account only a wired environment. Accordingly, when it is assumed that a terminal does not move in the wired environment, the terminal maintains connections with other nodes through an IP address assigned only once.

However, with the development of wireless technology, terminals located in the current IP network must be able to stably transmit and receive voice and data while being mobile.

Accordingly, a home network (HN) continuously tracks the location of a terminal changing location and stores information of the tracked location in a home agent (HA), such that the terminal to which a fixed IP address is assigned can normally transmit and receive voice and data while on the move. The term “HN” refers to a network in which the terminal to which an IP address is assigned is initially registered.

With ever increasing demand for Internet service, Internet Protocol version 4 (IPv4), which is currently being used, has problems of a growing shortage of available resources such as IPv4 addresses, IPv4 mobility and security weakness, etc. Therefore to address theses problems, Internet Protocol version 6 (IPv6) has been developed. Further, Mobile IPv6 (MIPv6) supports mobility of the IPv6.

FIG. 1 illustrates a network architecture based on a basic configuration of a conventional MIPv6. Referring to FIG. 1, MIPv6 network components include mobile nodes (MNs), a home agent (HA), a router, etc. Further, MIPv6 networks can be an HN, an Internet network, a foreign network (FN), etc.

More specifically, MN1 110 and MN2 170, which are mobile terminals for performing a packet communication function, are assigned mobile IP addresses. An HN 100 is a network in which the MNs 110 and 170 are initially registered, and an HA 120 manages registration information of the MNs 110 and 170. Further, the MN2 170, which is initially registered in the HN 100, can move from the HN 100 to a different network, i.e., an FN 140.

As described above, when moving from the HN 100 to the FN 140, the MN2 170 cannot use the IP address initially assigned thereto by the HN 100. Accordingly, the FN 140 newly assigns, to MN2 170, a care of address (CoA) available therein, such that MN2 170 can communicate within the FN 140.

A size of an IP address assigned to the MN in the MIPv6 environment is 128 bits. More significant bits of the 128 bits are designated as a prefix value for identifying a network, and less significant bits of the 128 bits are designated as an address value of Layer 3 (L3) for identifying a terminal. When MN2 170 moves from the HN 100 to the FN 140, a router 150 of the FN 140 identifies L3 information of the IP address of MN2 170, and determines that the FN 140 has been visited by MN2 170. In this case, the router 150 identifies a prefix value of the IP address of MN2 170, and generates a new L3 address according to predetermined guidelines. More specifically, the router 150 determines if a duplicate address corresponding to the generated L3 address is present. If no duplicate address is present, the generated L3 address is assigned to MN2 170.

When MN2 170 moves from the current network to another network, the FN 140 assigns, to the MN2 170, a CoA, which is as a temporary IP address, separately from an IP address assigned by the HN 100, such that MN2 170 can communicate using the CoA.

Even though MN2 170 has moved to the FN 140, all data transmitted to MN2 170 is sent to a network in which MN2 170 was initially registered, i.e., the HN 100. Therefore, the HN 100 must have location information of MN2 170 in order to transmit the data to MN2 170.

When MN2 170 moves to the FN 140 and is assigned a new CoA, the router 150 of the FN 140 binds the temporary IP address, i.e., the CoA information and the IP address of MN2 170 used in the HN 100, includes a result of the binding in a binding update (BU) message, and transmits the BU message to the HA 120 through an Internet network 130 (as indicated by reference numeral 180).

Upon receiving the BU message, the HA 120 identifies the BU message and stores the IP address of MN2 170 used in the HN 100 and the CoA assigned by the FN 140 in a predetermined table. Thereafter, the HA 120 intercepts packets transmitted to a home IP address of MN2 170, i.e., a network address of the HN 100, as a destination address, and transmits the intercepted packets to the FN 140.

More specifically, the HA 120 determines that a received packet is to be transmitted to MN2 170, and identifies the CoA of MN2 170 by referring to the table. Then, the HA 120 encapsulates the packet to attach a header to the packet, sets a destination address to the CoA of MN2 170, and transfers the encapsulated packet to MN2 170 (as indicated by reference numeral 185). In this case, the HN 100 and the FN 140 are tunneled for the MN2 170.

Conventionally, only a single network was taken into account. However, with the development of various wireless Internet environments, a mobile network environment has an increasingly complex structure in which a network includes a subnet and the subnet includes a smaller subnet, etc.

The conventional IPv6 technology does not support multiple and nested subnets, and thus has a problem in which a packet transfer may be interrupted. To address this problem, the Internet Engineering Task Force (IETF), the standards-setting body of the Internet, has organized a Network Mobility (NEMO) working group (WG) to develop the mobile technology standardized by the conventional mobile IP WG.

FIG. 2 illustrates a network architecture using a conventional NEMO basic support protocol. Referring to FIG. 2, the NEMO basic support protocol supports transparent NEMO for all MNs located within a mobile network (MONET) using bi-directional tunnels 260 and 270 between MRs and HAs.

An MR is responsible for managing NEMO. When moving from an HN 200 or 215 to an FN 230, the MR registers its own location information and a mobile network prefix (MNP) used for the MONET in an HA 205 or 220 located in the HN 200 or 215. In the location registration, prefix scope binding update (PSBU) is performed in extended MIPv6.

For convenience of explanation, an HA in which a predetermined MR is initially registered is denoted by “MR_HA”. Accordingly, an HA of MR1 210 of FIG. 2 is MR1_HA 205, and an HA of MR2 225 is MR2_HA 220. When a new network, i.e., an FN, is visited by a predetermined MR, the MR is assigned a CoA. The assigned CoA is denoted by “MR_CoA”. As described above, the MR1_HA 205 and the MR2_HA 220 store location information of the MR1 210 and the MR2 225. Whenever the MR is on the move, binding update (BU) is performed and then location information of the MR is stored.

After the MNP is registered, the bi-directional tunnel 260 is established between the MR1 240 and the MR1_HA 205. A correspondent node (CN) 280 serving as an arbitrary Internet node and MNs (i.e., MN1 and MN2) can transmit and receive data under transparent mobility support.

In FIG. 2, when the MR1 210 moves to the FN 230 (as indicated by reference numeral 250), the FN 230 assigns a CoA to MR1 240 moved thereto.

The CN 280 stores a home IP address of MR1 210, and transmits a packet to an address of the MN2 serving as a destination address. Because the destination address of the transmitted packet is a home IP address of the MN2, the packet is transferred to the MR1_HA 205 through an Internet network.

The MR1_HA 205 intercepts a packet associated with an MNP of MN2, and acquires a CoA of a point connected to the current MONET from information registered in a binding cache (BC). Thereafter, MR1_HA 205 refers to an acquired CoA of MR1, and tunnels the intercepted packet through the bi-directional tunnel 260. The tunneled packet is encapsulated such that it has a source address of MR1_HA, and a destination address corresponding to a CoA of MR1 (i.e., MR1_CoA). The packet is transferred to the MR1 240 through a router 235 of the FN 230 according to a tunneled path. The MR1 240, receiving the tunneled packet, serves as an endpoint of the tunnel, and transfers the packet to the MN2, which is as a destination within the network, after decapsulating the packet.

Now, a packet transfer process from the MN1 to the CN 280 will be described with reference to FIG. 2.

The MR1 240 encapsulates the packet transferred from an ingress interface, and transfers the encapsulated packet to the tunnel 260 established between MR1 240 and the HA 205 (i.e., MR1_HA). A source address of the encapsulated packet is a CoA of MR1 240 (i.e., MR1_CoA), and a destination address of the encapsulated packet is an address of an HA registered in a binding update list (BUL). Here, the BUL is used to manage the BU performed by MR1 240. When a tunneled packet 265 arrives at the MR1_HA 205, the MR1_HA 205 decapsulates the packet and routes the decapsulated packet to the CN 280 serving as the final destination.

When the MONET is present in the original HN, a packet is transferred by a conventional IPv6 routing technique. The HA maintains and manages the BC to determine if the MONET is present in the HN. When a BU with a lifetime value of 0 is received from an MR, an entry registered in the BC is invalid. That is, when the MR determines that it is located in the HN, the MR transmits, to the HA, a BU message in which a lifetime value is set to zero, and notifies the HA of its own presence in the HN.

In FIG. 2, the MR2 225 is similar to the MR1 210. That is, the MR2 225 can move from the HN 215 of MR2 225 to a new network (i.e., the FN 230). In this case, MNs (i.e., MN3 and MN4) associated with MR2 225 move together. When the FN 230 assigns a new CoA to the MR2 245 according to the move and transmits, to MR2_HA, a BU message corresponding to CoA assignment information, the tunnel 270 is established between the MR2 245 and the MR2_HA 220.

As described above, a packet from the CN 280 to the MN3 or the MN4 is intercepted by the MR2_HA 220, and the intercepted packet is transmitted to the MR2 245 through a path formed by the tunnel 270. When the packet received by the MR2 245 is destined for an MN (i.e., MN3 or MN4) managed by MR2 245, it is transmitted to a corresponding MN.

In the NEMO service, multi-homing in which one MONET has a plurality of interfaces is enabled. That is, the one MONET can have at least one MR, and an MR can have at least one interface. Accordingly, when an obstacle occurs in an arbitrary MR or a service for access to the MR, an access connection must be able to be dynamically changed. Accordingly, the MR needs to determine if a neighboring MR with an alternative path in the current network is present. To discover an alternative MR, the MR collects information of neighboring MRs by transmitting and receiving a router advertisement (RA) message of the existing IPv6.

The format of the conventional RA message is shown in Table 1 below.

TABLE 1

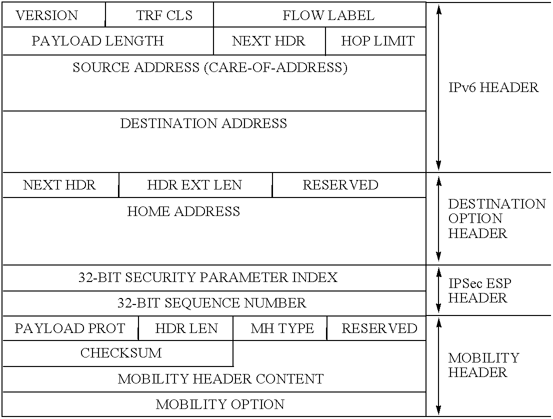

As seen from Table 1, the IPv6 header includes a 40-byte common header field and a destination address field. For security, a rear part of the packet is encrypted using a security parameter index of the IPsec Encapsulating Security Payload (ESP) header shared between the MR and the HA. A “MOBILITY HEADER” field is provided in relation to the MIPv6. A BU message or binding acknowledgement message associated with a type of the “MOBILITY HEADER” field is included in a “MOBILITY HEADER CONTENT” field. A necessary option is additionally included in a “MOBILITY OPTION” field.

A conventional process for identifying neighboring routers through an RA message exchange and recovering a tunnel when radio link failure occurs will be described with reference to FIGS. 3 and 4 below.

FIG. 3 illustrates a network architecture for identifying neighboring routers by exchanging an RA message between conventional MRs. Referring to FIG. 3, MR1 306 and MR2 314 include their router information in RA messages, and transmit the RA messages to neighboring routers. The RA message can be transmitted in response to a router solicitation (RS) message. Alternatively, the MRs 306 and 314 may periodically transmit the RA messages.

Upon receiving the RA messages, the MRs 306 and 314 acquire home addresses (HoAs), CoAs, and MNPs associated with the neighboring MRs. That is, MR1 306 and MR2 314 transfer CoAs assigned from access routers (ARs) 304 and 312 newly accessing HA1 302 and HA2 310 and the MNPs assigned to internal networks managed by the MRs 306 and 314 to HA1 302 and HA2 310 through BU messages, such that data can be transferred to the ARs 304 and 312 currently performing access. The BU messages are periodically transferred from the MRs 306 and 314 to the HAs 302 and 310, such that information of current connection states of the MRs 306 and 314 is reported. In this case, the MRs 306 and 314 transmit the RA messages to report the presence of the MRs 306 and 314 to the neighboring routers and MNs 308, 316, and 318 of subnets managed thereby. When receiving an RA message from a neighboring MR, an arbitrary MR acquires information of the neighboring MR.

FIG. 4 illustrates a network architecture for recovering a tunnel by an MR when radio link failure occurs. Referring to FIG. 4, when a link currently being used between HA1 402 and MR1 404 is damaged due to signal reduction of a radio channel or failure of the link itself, the MR1 404 refers to the known information and generates a new tunnel directed to a neighboring MR (e.g., MR2 412). The MR1 404 is assigned a new CoA, and transmits a BU message to HA1 402 through the MR2 412. In this case, a tunnel must be present or generated between HA1 402 and HA2 416 serving as a home agent of MR2 412. MR1 404 maintains communication with the HA1 402 by using the newly generated tunnel and the existing tunnel.

An MR-based tunnel recovery process after a radio link failure has been described with reference to FIG. 4. However, there is also a possibility that a tunnel cannot be recovered due to failure of the MR itself. In a process for selecting a neighboring MR as an alternative router in an MR having suffered radio link failure, reliable tunnel recovery may be difficult due to the presence of a fake MR.

Accordingly, the prior art has the following problems.
(1) Link loss due to the occurrence of radio link failure.
(2) Tunnel recovery disabled due to failure of an MR itself.

The first problem, i.e., the link loss due to the occurrence of radio link failure, may be caused by an increased error rate of a radio channel, an increased interference signal, etc. To address this problem, the MR whose communication function is disabled because of the radio link failure selects one of the neighboring MRs, and generates a new tunnel to maintain the current connection through the selected MR.

In the second problem, a router node may be disabled because of computational resource loss, buffer resource loss, or network resource loss caused by a denial of service (DoS) attack launched by a malicious user. When the router node is shut down because of a physical bug or software bug, service can be disabled. When the router node malfunctions, tunnel recovery based on the router node cannot be performed.

More specifically, when the router node is disabled by an attack launched by a malicious user, data to be transferred to the router node may be wrongly transferred to the malicious user. Accordingly, a need exists for a method capable of reliably recovering a tunnel for an MR while avoiding such an attack.

### SUMMARY OF THE INVENTION

It is, therefore, an aspect of the present invention to provide a method and system that can quickly recover a tunnel when radio link failure occurs by registering in advance neighboring mobile routers (MRs) in a home agent (HA) provided in a mobile network.

It is another aspect of the present invention to provide a method and system that can reliably recover a home agent (HA)-based tunnel according to neighboring mobile router (MR) information registered in advance when operation of an MR is disabled in a mobile network.

The above and other aspects of the present invention can be achieved by a method for recovering a routing path between a first router and at least one mobile node in a mobile network including the first router for managing a first subnet having at least one second router and the at least one second router managing a second subnet including the at least one mobile node. The method comprises receiving, from the at least one second router, information of neighboring routers included in the first subnet; storing the received neighboring router information in the first router; recognizing a routing path failure when a periodic report message is not received from the at least one second router within a preset time; selecting an alternative router among the neighboring routers, when the routing path failure is recognized; requesting a routing path recovery to the alternative router; and routing data to the at least one mobile node through the alternative router, when the alternative router positively responds to the routing path recovery request.

The above and other aspects of the present invention can be achieved by a method for registering, in a home agent, a location of at least one neighboring mobile router included in a different network in a mobile network including a first network and a second network, which is different from the first network, each of the first and second networks including a home agent, each of the home agents storing location information of a plurality of mobile routers of the network to which the home agent belongs. The method comprises receiving, from the at least one neighboring mobile router located in the different network, a router advertisement message in a mobile router located in the network in which the home agent is present; acquiring address information of the at least one neighboring mobile router included in the router advertisement message in the mobile router; transmitting the acquired address information from the mobile router to the home agent thereof; and registering the location of the at least one neighboring mobile router by storing the address information in the home agent.

The above and other aspects of the present invention can be achieved by a system for recovering a routing path between a first router and at least one mobile node in a mobile network having a nested structure in which the first router manages a first subnet including at least one second router and the at least one second router manages a second subnet including the at least one mobile node. The system comprises a plurality of neighboring routers included in the first subnet; and a home agent for receiving, from the at least one second router, information of the plurality of neighboring routers included in the first subnet, storing the received neighboring router information, recognizing a routing path failure when a periodic report message is not received from the at least one second router within a preset time, selecting an alternative router from among the plurality of neighboring routers when the routing path failure is recognized, sending a routing path recovery request to the alternative router, and routing data to the at least one mobile node through the alternative router, when the alternative router positively responds to the routing path recovery request, wherein the neighboring routers each transmit a tunnel recovery response to the home agent in consideration of a load of processing data traffic, when a tunnel recovery request is received from the home agent.

The above and other aspects of the present invention can be achieved by a system for registering, in a home agent, a location of at least one neighboring mobile router included in a different network, in a mobile network including a first network and a second network, which is different from the first network, each of the first and second networks including a home agent, each of the home agents storing location information of a plurality of mobile routers of the network to which the home agent belongs. The system comprises a home agent; and a mobile router for receiving a router advertisement message from the at least one neighboring mobile router located in the different network, acquiring address information of the at least one neighboring mobile router included in the router advertisement message, and transmitting the acquired address information to the home agent, wherein the home agent registers the location of the at least one neighboring mobile router by receiving and storing the acquired address information.

### BRIEF DESCRIPTION OF THE DRAWINGS

The above and other aspects and advantages of the present invention will be more clearly understood from the following detailed description taken in conjunction with the accompanying drawings, in which:

FIG. 1 illustrates a network architecture based on a basic configuration of a conventional Mobile Internet Protocol version 6 (MIPv6);

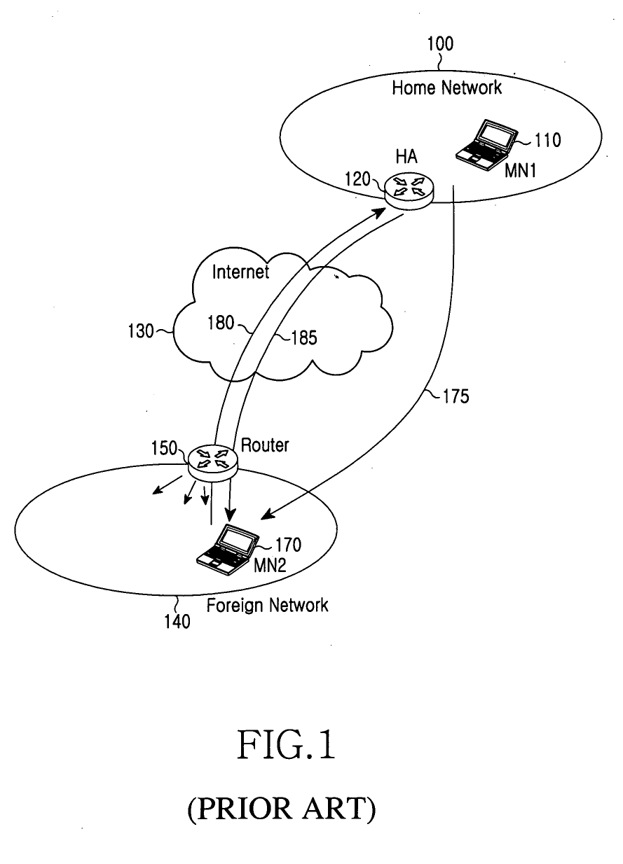

FIG. 2 illustrates a network architecture using a conventional Network Mobility (NEMO) basic support protocol;

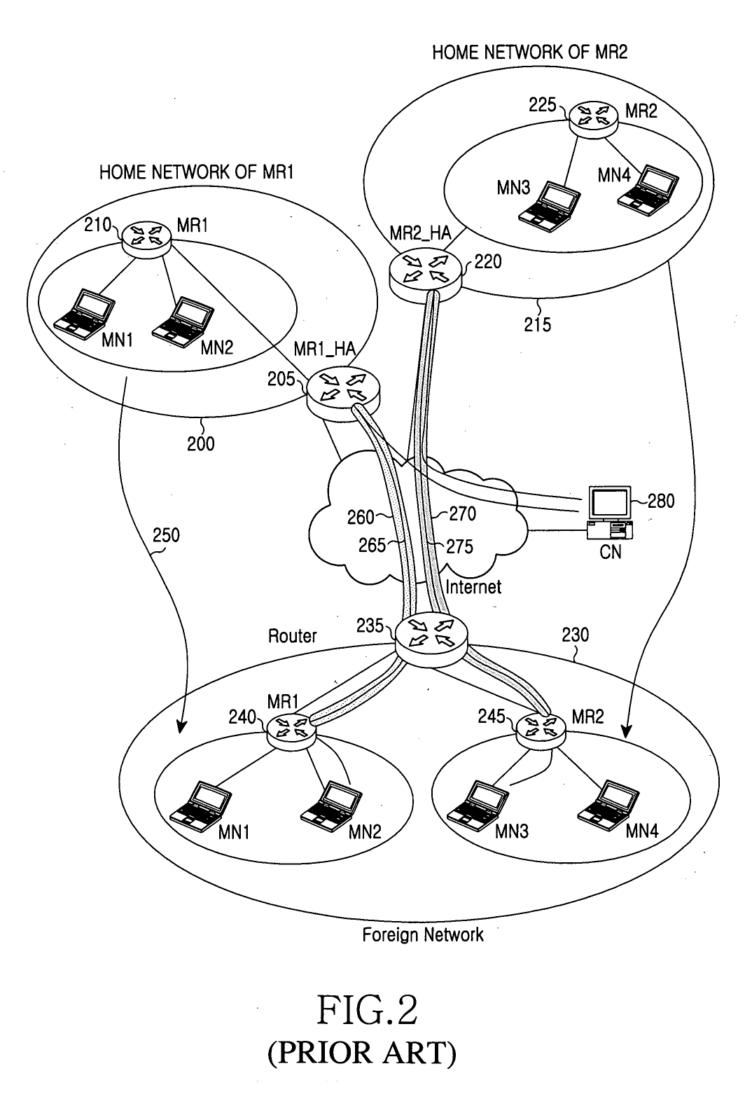

FIG. 3 illustrates a network architecture for discovering neighboring routers by exchanging an RA message between conventional mobile routers (MRs);

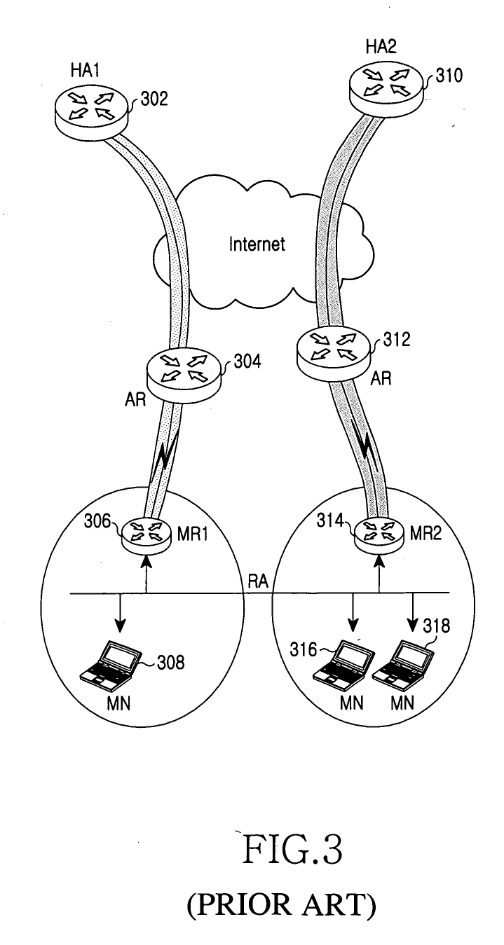

FIG. 4 illustrates the network architecture for recovering a tunnel by an MR when radio link failure occurs;

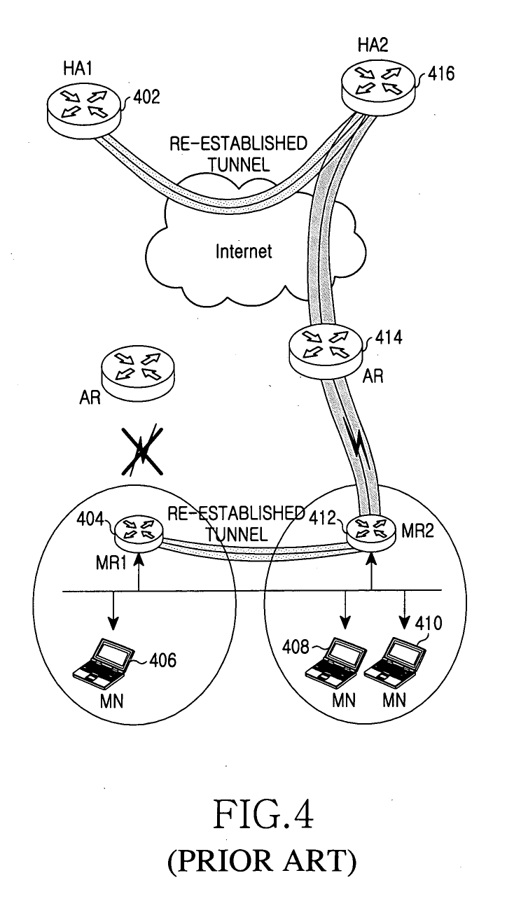

FIG. 5 illustrates a network architecture for identifying, authenticating, and registering a router node on the basis of a home agent (HA) of a mobile network in accordance with an embodiment of the present invention;

FIG. 6 is a ladder diagram illustrating a procedure for identifying, authenticating, and registering a router node using an HA of a mobile network in accordance with an embodiment of the present invention;

FIG. 7 illustrates the network architecture for performing a tunnel recovery procedure using an HA of the mobile network in accordance with an embodiment of the present invention; and

FIG. 8 is a ladder diagram illustrating the tunnel recovery procedure of an HA of the mobile network in accordance with an embodiment of the present invention.

### DETAILED DESCRIPTION OF THE PREFERRED EMBODIMENTS

Preferred embodiments of the present invention will be described in detail herein below with reference to the accompanying drawings. In the following description, a detailed description of known functions and configurations incorporated herein will be omitted for conciseness.

The present invention relates to a method for recovering a damaged tunnel in the proposed Mobile Internet Protocol version 6 (MIPv6) for supporting host mobility in Internet Protocol version 6 (IPv6) serving as the next generation Internet protocol. Moreover, the present invention proposes a method for quickly and reliably recovering a router path or tunnel damaged due to the occurrence of radio link failure or a disabled router node.

A large amount of research is being done to develop an all-IP based network for assigning an IP address to all nodes of the mobile network. Accordingly, the IPv6 for extending the length of an IP address of IPv4 from 32 bits to 128 bits is being studied. The MIPv6 enables support for mobility in the IPv6. Basic service requirements necessary for Network Mobility (NEMO) based on the MIPv6 are defined in the NEMO basic support protocol proposed by the NEMO Working Group (WG).

The NEMO basic support protocol defines a function for integrating and managing mobility of mobile nodes (MNs) belonging to a subnet managed by a mobile router (MR) and a new binding update (BU) protocol function for location registration, etc. Further, the NEMO basic support protocol proposes a multihoming scheme having a plurality of MRs or interfaces, or a plurality of MRs and home agents (HAs) for connecting one mobile network (MONET) to another network. The multihoming scheme has been proposed to generate multiple connections when a terminal does not receive service after a radio link of the MONET is released or a router malfunctions. The multihoming scheme can be used to dynamically distribute a load by replacing a specific router path with an alternative router path. For example, when the overload of data traffic processing occurs, an MR of the present invention may not arbitrarily transmit a periodic BU message or may release a link without sending a router advertisement message to neighboring MRs. In this case, a neighboring MR can serve as an alternative MR in place of the MR whose link is released.

Because a router node or router can perform the same function as the MR, the MR is referred to as the router node or router. When a tunnel is recovered, an arbitrary router node can be selected among a plurality of neighboring router nodes located on a router path. Herein, the selected router node is referred to as the alternative router.

When one of the MRs is disabled as indicated by the problems occurring in the prior art, communication functions of low-level mobile nodes (MNs) associated with the disabled MR are also disabled. Further, a delay time occurs due to tunnel recovery when a radio link or router node fails in the MONET, such that a continuous communication service cannot be provided between nodes.

Accordingly, the present invention performs an HA-based tunnel recovery, which is different from the conventional MR-based tunnel recovery. The HA authenticates and registers in advance neighboring router nodes, i.e., neighboring MRs, and selects the optimum alternative MR among the registered MRs when a radio link or router node has failed, such that a tunnel can be quickly recovered. The HA defines a new message format and hence can perform tunnel recovery based on enhanced security. In the present invention, the HA performs the following functions to overcome the problems occurring in the conventional tunnel recovery.
A. Neighboring router detection, authentication, and registration.
B. Neighboring router list deletion and tunnel connection release.
C. Tunnel recovery through an alternative router.

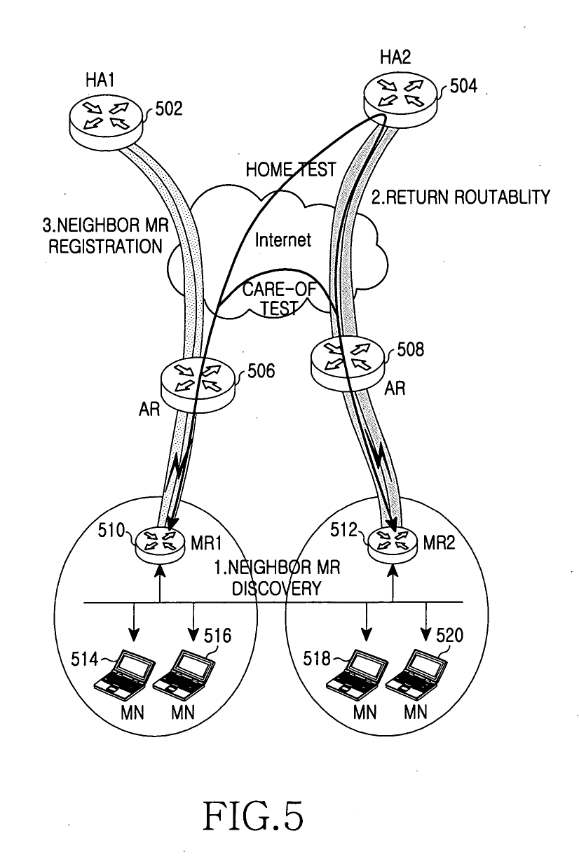

FIG. 5 illustrates a network architecture for identifying, authenticating, and registering a router node using an HA of the MONET in accordance with an embodiment of the present invention. Referring to FIG. 5, HA1 502 and HA2 504 manage MR1 510 and MR2 512, respectively. MR1 510 and MR2 512 manage a plurality of MNs in respective subnets.

In the present invention, the HA1 502 and the HA2 504 perform the following procedures until a neighboring router is registered.
A1. Neighboring router detection
A2. Neighboring router authentication
A3. Neighboring router registration

The neighboring router detection will be described herein below. The HA1 502 and the HA2 504 assign care of addresses (CoAs) to MR1 510 and MR2 512 through access routers (ARs). The MR1 510 and the MR2 512 to which the CoAs are assigned transmit mobile network prefixes (MNPs), assigned to subnets, to their HAs through BU messages. A BU message is periodically transmitted to an HA, such that the HA can identify nodes registered therein or a tunnel state from the BU message. Here, the MRs 510 and 512 transmit and receive router advertisement (RA) or router solicitation (RS) messages to report the presence of the MRs 510 and 512 to the neighboring MRs and MNs 514, 515, 518, and 520 of subnets.

Upon receiving the RA or RS message, the MR records its own address information, transmits the address information to other neighboring MRs, and records, in the neighboring MR list, a neighboring MR transmitting the RA or RS message. The MR discovers the neighboring MRs by transmitting the RA or RS message, and information of the discovered neighboring MRs is transmitted to the HA through the BU message, such that the neighboring MR detection procedure is completed.

Subsequently, the HA performs an authentication procedure according to the information of the detected neighboring MRs. The authentication procedure uses a return routability procedure as one of the basic procedures defined in the conventional MIPv6. That is, the return routability procedure is an authentication procedure for identifying a home address (HoA) and a CoA. Messages, used to identify the HoA and CoA, include a home test initiation message, a home test message, a CoA test initiation message, and a CoA test message. The messages are transmitted between MRs and their neighboring MRs and between the MRs and HAs. That is, the MR transmits the CoA test message and the CoA test initiation message to, and receives the CoA test message and the CoA test initiation message from, a neighboring MR, thereby identifying the neighboring MR. The MR transmits the home test message and the home test initiation message to, and receives the home test message and the home test initiation message from, a corresponding HA of the neighboring MR, thereby determining if the neighboring MR is a fake MR through a double authentication procedure.

Upon completing the return routability procedure, the MR stores neighboring MR information, i.e., an HoA, a CoA, and an MNP, in a neighboring MR list, and transmits a BU message to an HA associated therewith.

In accordance with the present invention, the BU message includes a neighboring MR registration option in a mobility option field. Accordingly, the HA identifies an HoA, a CoA, and an MNP of a neighboring MR from the received BU message.

Table 2 shows a format of the neighboring MR registration option message included in the mobility option field of the BU message.

TABLE 2

| | | | |
|---|---|---|---|
| Type | Length | Reserved | Prefix Length |

Home Address (HoA)
Care of Address (CoA)
Mobile Network Prefix (MNP)

As shown in Table 2, the format of the neighboring MR registration option message includes a “Type” field for indicating the neighboring MR registration option message, a “Length” field for indicating the total length of the option message, a “Prefix Length” field for indicating the length of an MNP, an “HoA” field for indicating an HoA of the MR, a “CoA” field for indicating a CoA of the MR, and an “MNP” field for indicating the MNP. The neighboring MR registration option message may include a plurality of option messages corresponding to the number of neighboring MRs.

Upon receiving the neighboring MR registration option message from the MR, the HA registers the HoA, the CoA, and the MNP as neighboring MR information.

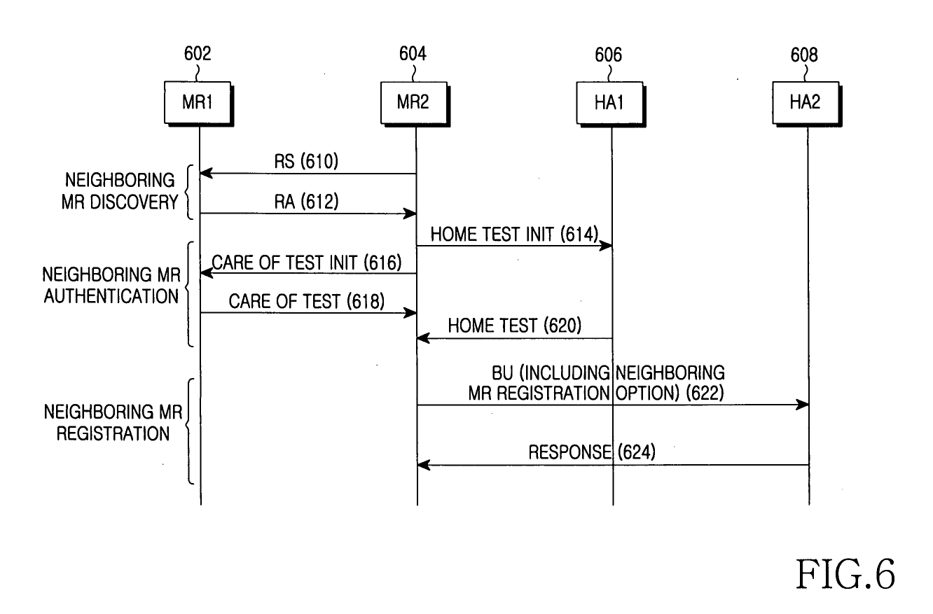

FIG. 6 is a ladder diagram illustrating a procedure for detection, authenticating, and registering a router node using an HA of a mobile network in accordance with an embodiment of the present invention. Referring to FIG. 6, the MR2 604 transmits an RS message to MR1 602 serving as a neighboring router node to determine the presence of MR1 602 in Step 610. In response to the RS message, the MR1 602 transmits an RA message to MR2 604 in Step 612. The RA message can be transmitted as a response to the RS message, and may be an unsolicited message capable of being transmitted without receiving the RS message.

After steps 610 and 612 are performed, the MR2 604 determines the presence of the MR1 602 serving as the neighboring router node. As described above, the MR2 604 transmits the RS message to the MR1 602 serving as the neighboring router node. Alternatively, MR2 604 may be the neighboring router node of MR1 602.

After performing a neighboring MR detection procedure, the MR2 604 transmits a home test initiation message to the HA1 606, such that an authentication procedure of MR1 602 can be performed in Step 614. The MR2 604 transmits a CoA test initiation message to MR1 in Step 616. The MR2 604 receives, from the MR1 602, a CoA test message as a response to the CoA test initiation message in Step 618, and receives, from the HA1 606, a home test message as a response to the home test initiation message in Step 620. After the authentication procedure of MR1 602 is completed in step 620, the MR2 604 transmits a BU message to the HA2 608 in accordance with the present invention in Step 622.

The HA2 608 identifies information of an HoA, a CoA, and an MNP recorded in a neighboring MR registration option field included in a mobility option field of the BU message transmitted from the MR2 604, registers the information of the MR1 602, and transmits a response to MR2 604 in Step 624.

A neighboring MR registered in the HA can be deleted from the neighboring MR list in the following case. That is, the neighboring MR may be out of the range of a network managed by the HA or its radio link may fail. In this case, the neighboring MR transmits, to its neighboring MRs, an RA message whose router lifetime field has been set to 0, such that the fact that it does not periodically transmit an RA message to the MRs, or no longer serves as a neighboring MR can be reported.

When a corresponding MR does not periodically transmit an RA message or transmits an RA message whose router lifetime field has been set to 0, it is deleted from the neighboring MR list.

Subsequently, when transmitting a BU message newly defined in accordance with the present invention, an arbitrary MR does not include information of a failed neighboring MR in the BU message. Immediately before the lifetime of a BU message expires, the HA sends a request message to request that an MR transmit a new BU message. When the MR does not transmit a new BU message in response to the BU message request, the HA determines that the MR or its link has failed.

When an MR or its radio link has failed, the HA selects the optimum alternative MR from among the registered neighboring MRs and recovers a tunnel, such that data can be smoothly transmitted and received. A process in which the HA recovers a tunnel by using the alternative MR will be described herein below.

First, the HA recognizes the occurrence of tunnel failure when it does not receive a periodic BU message or a heartbeat message for checking a tunnel connection state, or does not detect data transferred through a bi-directional tunnel for a predetermined time.

Upon recognizing the occurrence of tunnel failure, the HA selects an alternative MR from the neighboring MR list in place of an MR associated with the failure. In this case, a message to be sent from the HA to the alternative MR uses a tunnel recovery request message inserted into a destination option header of a BU message newly defined in accordance with the present invention. The format of the tunnel recovery request message is shown in Table 3 below.

TABLE 3

| | | | |
|---|---|---|---|
| Next Hdr | Length | Reserved | Prefix Length |

Home Address (HoA)
Care of Address (CoA)
Mobile Network Prefix (MNP)

As shown in Table 3, the format of the tunnel recovery request message includes a “Next Hdr” field for indicating a type of the next header, a “Length” field for indicating the total length of the message, a “Prefix Length” field for indicating the length of an MNP, an “HoA” field for indicating an HoA, a “CoA” field for indicating a CoA, and an “MNP” field for indicating the MNP.

The HA transmits a BU message including the tunnel recovery request message to the alternative MR. Upon receiving the BU message, the alternative MR transmits a tunnel recovery response message to the HA. The format of the tunnel recovery response message is shown in Table 4 below.

TABLE 4

| | | | |
|---|---|---|---|
| Next Hdr | Payload Length | G | Reserved |

MR Care-of-Address (CoA)

As shown in Table 4, the tunnel recovery response message is included in a destination option header as in the tunnel recovery request message. A “G” field is indicated by a binary value. The HA identifies the binary value indicated in the “G” field to determine if the alternative MR has granted or denied the tunnel recovery request. For example, when the binary value of the “G” field is 1, the alternative MR has granted the tunnel recovery. However, when the binary value of the “G” field is 0, the alternative MR has denied the tunnel recovery.

When the HA has received the tunnel recovery response message indicating that the alternative MR has granted the tunnel recovery, it tunnels data through the alternative MR. However, when the alternative MR has not granted the tunnel recovery, the HA identifies another alternative MR to send the tunnel recovery request to the another alternative MR.

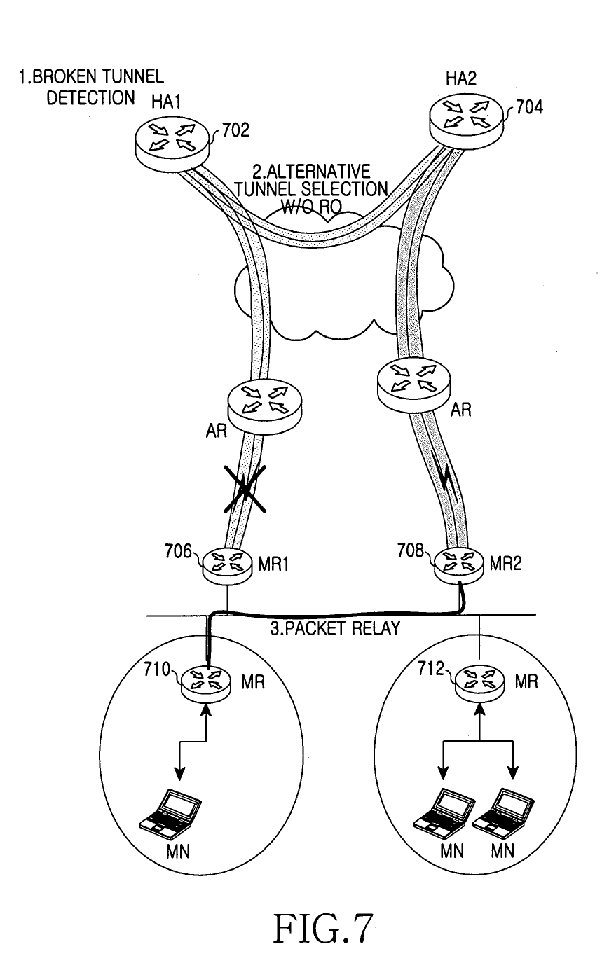

FIG. 7 illustrates a network architecture for performing a tunnel recovery procedure using an HA of the mobile network in accordance with an embodiment of the present invention. Referring to FIG. 7, when the HA1 702 does not receive a periodic BU message, it recognizes the occurrence of failure of a tunnel or the MR1 706. Upon recognizing the failure occurrence, the HA1 702 sends a tunnel recovery request message to MR2 708 serving as an alternative MR, and then attempts to recover the tunnel.

Upon receiving the tunnel recovery request message, the MR2 708 sends, to the HA1 702, a response message indicating that the tunnel recovery request has been granted. Then, the HA1 702 can recover the tunnel according to nested tunneling of HA1->HA2->MR2 using the NEMO basic support protocol.

When a tunnel from the HA1 702 to the MR2 708 is recovered, the MR2 708 receives data to be transferred to the MR1 706, and decapsulates the received data, such that a packet is relayed to MN 712 through a MR 710. Consequently, the HA1 702 can quickly and securely recover a tunnel when tunnel or MR failure occurs.

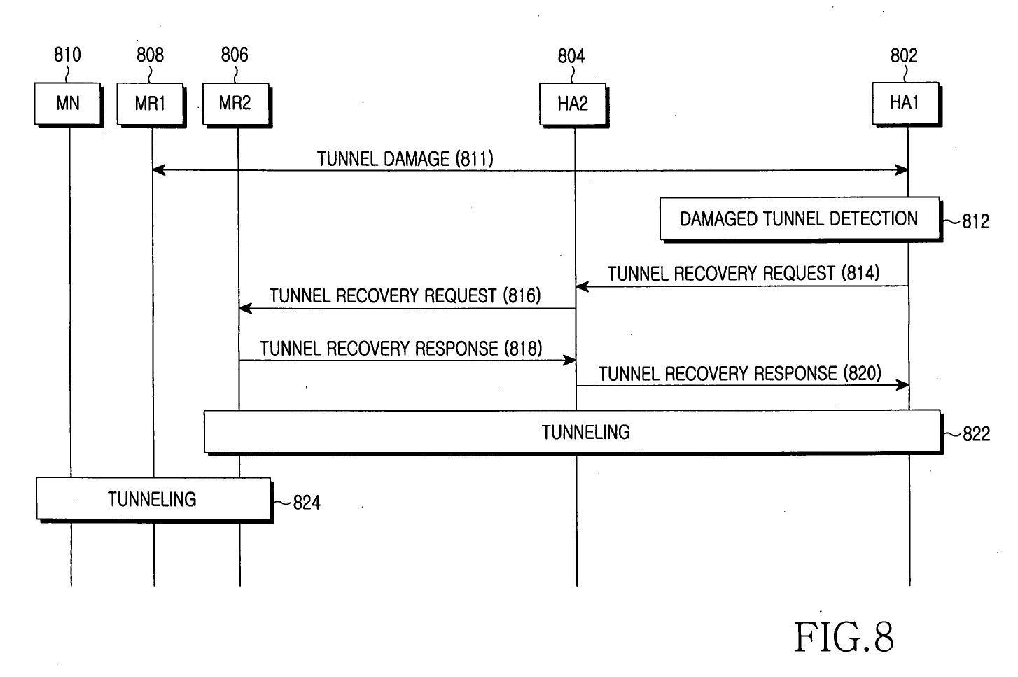

FIG. 8 is a ladder diagram illustrating a tunnel recovery procedure using an HA of the mobile network in accordance with an embodiment of the present invention. Referring to FIG. 8, HA1 802 recognizes a failure of a bi-directional tunnel connected to a corresponding MR when it does not receive a periodic BU message or a heartbeat message for checking a tunnel connection state in Step 812. Accordingly, the HA1 802 sends a tunnel recovery request message to a destination of the MR2 806 selected as an alternative MR for tunnel recovery. The tunnel recovery request message is first sent to the HA2 804 in Step 814. The HA2 804 relays the tunnel recovery request message to the MR2 806 in Step 816.

When receiving the tunnel recovery request message, the MR2 806 determines a response to the tunnel recovery request by taking into account the presence of idle resources.

When the MR2 grants a tunnel recovery request, the MR2 806 sends, to the HA1 802, a tunnel recovery response message indicating that tunnel recovery has been granted. The tunnel recovery response message is sent to HA2 804 in Step 818. The HA2 804 relays the message to the HA1 802 in Step 820. According to the granted tunnel recovery, the HA1 802 tunnels data to the MR2 806, such that a previous session between the HA1 802 and the MR1 808 can be maintained. When a tunnel from the HA1 802 to the MR2 806 is recovered in Step 822, the MR2 806 decapsulates encapsulated data and generates a tunnel between the MR2 806 and the MR1 808 in Step 824, such that data is routed to an MN 810.

As is apparent from the above description, the present invention can register, in advance, neighboring router nodes through authentication and registration procedures, and can delete a corresponding router node from a registration list when the router node has moved to a different network or has failed. Because a neighboring MR list capable of being registered or deleted is managed, the present invention can quickly and securely recover a tunnel when a radio link or equipment has failed.

Although preferred embodiments of the present invention have been disclosed for illustrative purposes, those skilled in the art will appreciate that various modifications, additions, and substitutions are possible, without departing from the spirit and the scope of the present invention. Therefore, the present invention is not limited to the above-described embodiments, but is defined by the following claims, along with their full scope of equivalents.

1. A method for recovering a routing path between a first router and at least one mobile node in a mobile network including the first router for managing a first subnet having at least one second router and the at least one second router managing a second subnet including the at least one mobile node, the method comprising:
receiving, from the at least one second router, information of neighboring routers included in the first subnet;
storing the received neighboring router information in the first router;
recognizing a routing path failure when a periodic report message is not received from the at least one second router within a preset time;
selecting an alternative router among the neighboring routers, when the routing path failure is recognized;
requesting a routing path recovery to the alternative router; and
routing data to the at least one mobile node through the alternative router, when the alternative router positively responds to the routing path recovery request.

2. The method according to claim 1, wherein the neighboring router information is received through a binding update (BU) message.

3. The method according to claim 2, wherein the neighboring router information includes care of address (CoA) information, home address (HoA) information, and mobile network prefix (MNP) information of the neighboring routers.

4. The method according to claim 1, further comprising:
when information of a neighboring router is not present in the periodic report message, deleting the information of the neighboring router from the stored neighboring router information.

5. The method according to claim 1, wherein a response message sent from the alternative router includes care of address (CoA) information of the alternative router.

6. The method according to claim 5, wherein the response message includes a field indicating if the alternative router has granted tunnel recovery.

7. The method according to claim 1, further comprising:
authenticating the neighboring routers, when the neighboring router information is received.

8. The method according to claim 1, wherein the periodic report message is a binding update (BU) message.

9. A method for registering, in a home agent, a location of at least one neighboring mobile router included in a different network in a mobile network including a first network and a second network, which is different from the first network, each of the first and second networks including a home agent, each of the home agents storing location information of a plurality of mobile routers of the network to which the home agent belongs, the method comprising:
receiving, from the at least one neighboring mobile router located in the different network, a router advertisement message in a mobile router located in the network in which the home agent is present;
acquiring address information of the at least one neighboring mobile router included in the router advertisement message in the mobile router;
transmitting the acquired address information from the mobile router to the home agent thereof; and
registering the location of the at least one neighboring mobile router by storing the address information in the home agent.

10. The method according to claim 9, wherein the address information is care of address (CoA) information, home address (HoA) information, and mobile network prefix (MNP) information of the at least one neighboring mobile router.

11. The method according to claim 9, wherein the mobile router transmits a binding update (BU) message included the address information of the at least one neighboring mobile router to the home agent.

12. The method according to claim 9, further comprising:
transmitting a response message from the home agent to the mobile router, after the at least one neighboring mobile router is registered.

13. The method according to claim 9, wherein when a data processing overload occurs in the at least one neighboring mobile router, the mobile router operates as an alternative mobile router with which the at least one neighboring mobile router is replaced.

14. A system for recovering a routing path between a first router and at least one mobile node in a mobile network having a nested structure in which the first router manages a first subnet including at least one second router and the at least one second router manages a second subnet including the at least one mobile node, the system comprising:
a plurality of neighboring routers included in the first subnet; and
a home agent for receiving, from the at least one second router, information of the plurality of neighboring routers included in the first subnet, storing the received neighboring router information, recognizing a routing path failure when a periodic report message is not received from the at least one second router within a preset time, selecting an alternative router from among the plurality of neighboring routers when the routing path failure is recognized, sending a routing path recovery request to the alternative router, and routing data to the at least one mobile node through the alternative router, when the alternative router positively responds to the routing path recovery request,
wherein the neighboring routers each transmit a tunnel recovery response to the home agent in consideration of a load of processing data traffic, when a tunnel recovery request is received from the home agent.

15. The system according to claim 14, wherein the home agent receives the neighboring router information through a binding update (BU) message.

16. The system according to claim 15, wherein the home agent receives the neighboring router information including care of address (CoA) information, home address (HoA) information, and mobile network prefix (MNP) information of the neighboring routers.

17. The system according to claim 14, wherein when information of a neighboring router is not present in the periodic report message, the home agent deletes the information of the neighboring router from the stored neighboring router information.

18. The system according to claim 14, wherein the alternative router transmits, to the home agent, a response message including a care of address (CoA) of the alternative router.

19. The system according to claim 18, wherein the response message comprises a field indicating if the alternative router has granted tunnel recovery.

20. A system for registering, in a home agent, a location of at least one neighboring mobile router included in a different network, in a mobile network including a first network and a second network, which is different from the first network, each of the first and second networks including a home agent, each of the home agents storing location information of a plurality of mobile routers of the network to which the home agent belongs, the system comprising:
a home agent; and
a mobile router for receiving a router advertisement message from the at least one neighboring mobile router located in the different network, acquiring address information of the at least one neighboring mobile router included in the router advertisement message, and transmitting the acquired address information to the home agent,
wherein the home agent registers the location of the at least one neighboring mobile router by receiving and storing the acquired address information.

21. The system according to claim 20, wherein the address information comprises: care of address (CoA) information, home address (HoA) information, and mobile network prefix (MNP) information of the at least one neighboring mobile router.

22. The system according to claim 20, wherein the mobile router includes the address information of the at least one neighboring mobile router in a binding update (BU) message, and transmits the BU message to the home agent.

23. The system according to claim 20, wherein the home agent transmits a response message to the mobile router after registering the at least one neighboring mobile router.

24. The system according to claim 20, wherein when a data processing overload occurs in the at least one neighboring mobile router, the mobile router operates as an alternative mobile router with which the at least one neighboring mobile router is replaced.
